(19) United States
(12) Patent Application Publication
(10) Pub. No.: US 2022/0131062 A1
(43) Pub. Date: Apr. 28, 2022

(54) SOLID-STATE THERMOELECTRIC

(71) Applicant: LENOVO (Singapore) PTE. LTD., New Tech Park (SG)

(72) Inventors: Bouziane Yebka, Apex, NC (US); Joseph David Plunkett, Raleigh, NC (US); Philip Jakes, Durham, NC (US); Tin-Lup Wong, Chapel Hill, NC (US); Tadashi Kosuga, Tokyo (JP)

(21) Appl. No.: 17/083,170

(22) Filed: Oct. 28, 2020

(51) Int. Cl. H01L 35/32; H01L 35/34

(52) U.S. Cl. CPC H01L 35/32; H01L 35/34

(57) ABSTRACT

For thermoelectric heat transfer, a thermoelectric device includes a planar p-type semiconductor that is planar within a first plane, a planar n-type semiconductor that is coplanar with the planar p-type semiconductor within the first plane, a cold side conductor that is coplanar with the planar p-type semiconductor and the planar n-type semiconductor within the first plane and that connects to the planar p-type semiconductor and to the planar n-type semiconductor, and a hot side conductor that is coplanar with the planar p-type semiconductor and the planar n-type semiconductor within the first plane and that connects to the planar p-type semiconductor and to the planar n-type semiconductor. The thermoelectric device further includes a hot side substrate, a hot side thermal insulator, a cold side substrate, and a cold side thermal insulator. The cold side conductor draws heat from the cold side substrate.

### FIELD

The subject matter disclosed herein relates to sold-state thermoelectric devices.

### BACKGROUND

Thermoelectric devices transfer heat.

### BRIEF SUMMARY

A thermoelectric device for thermoelectric heat transfer is disclosed. The thermoelectric device includes a planar p-type semiconductor that is planar within a first plane, a planar n-type semiconductor that is coplanar with the planar p-type semiconductor within the first plane, a cold side conductor that is coplanar with the planar p-type semiconductor and the planar n-type semiconductor within the first plane and that connects to the planar p-type semiconductor and to the planar n-type semiconductor, and a hot side conductor that is coplanar with the planar p-type semiconductor and the planar n-type semiconductor within the first plane and that connects to the planar p-type semiconductor and to the planar n-type semiconductor. The thermoelectric device further includes a hot side substrate in thermal contact with the hot side conductor, a hot side thermal insulator that insulates the cold side conductor from the host side substrate, a cold side substrate in thermal contact with the cold side conductor, and a cold side thermal insulator that insulates the hot side conductor from the cold side substrate. The cold side conductor draws heat from the cold side substrate and the hot side conductor directs the heat to the hot side substrate in response to an electric current applied between the cold side conductor and the hot side conductor. A system and method also perform the functions of the thermoelectric device.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1A is a perspective drawing illustrating one embodiment of a thermoelectric device;

FIG. 1B is a side view drawing illustrating one embodiment of a first plane;

FIG. 1C is a side view drawing illustrating one embodiment of a thermoelectric device;

FIG. 1D is a side view drawing illustrating one embodiment of a cooling system;

FIG. 2A is a perspective drawing illustrating one alternate embodiment of a thermoelectric device;

FIG. 2B is a perspective drawing illustrating one alternate embodiment of a thermoelectric device;

FIG. 2C is a perspective drawing illustrating one alternate embodiment of a thermoelectric device;

FIG. 2D is a perspective drawing illustrating one alternate embodiment of a thermoelectric device;

FIG. 2E is a perspective drawing illustrating one alternate embodiment of a thermoelectric device;

FIG. 3A is a top view drawing illustrating one embodiment of cold side substrate in a fabrication process;

FIG. 3B is a side view drawing illustrating one embodiment of cold side substrate in a fabrication process;

FIG. 4A is a top view drawing illustrating one embodiment of grooving in a fabrication process;

FIG. 4B is a side view drawing illustrating one embodiment of grooving in a fabrication process;

FIG. 5A is a top view drawing illustrating one embodiment of thermal insulator deposition in a fabrication process;

FIG. 5B is a side view drawing illustrating one embodiment of thermal insulator deposition in a fabrication process;

FIG. 6A is a top view drawing illustrating one embodiment of conductor deposition in a fabrication process;

FIG. 6B is a side view drawing illustrating one embodiment of conductor deposition in a fabrication process;

FIG. 7A is a top view drawing illustrating one embodiment of p-type semiconductor and n-type semiconductor deposition in a fabrication process;

FIG. 7B is a side view drawing illustrating one embodiment of p-type semiconductor and n-type semiconductor deposition in a fabrication process;

FIG. 8A is a top view drawing illustrating one embodiment of hot side substrate deposition in a fabrication process;

FIG. 8B is a side view drawing illustrating one embodiment of hot side substrate and hot side thermal insulator deposition in a fabrication process; and

FIG. 9 is a schematic flow chart diagram illustrating one embodiment of a thermoelectric device fabrication method.

### DETAILED DESCRIPTION

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise. The term “and/or” indicates embodiments of one or more of the listed elements, with “A and/or B” indicating embodiments of element A alone, element B alone, or elements A and B taken together.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function or effect to one or more blocks, or portions thereof, of the illustrated Figures.

Although various arrow types and line types may be employed in a flowchart, they are understood not to limit the scope of the corresponding embodiments. Indeed, some arrows or other connectors may be used to indicate only one flow of the depicted embodiment.

The description of elements in each figure may refer to elements of proceeding figures. Like numbers refer to like elements in all figures, including alternate embodiments of like elements.

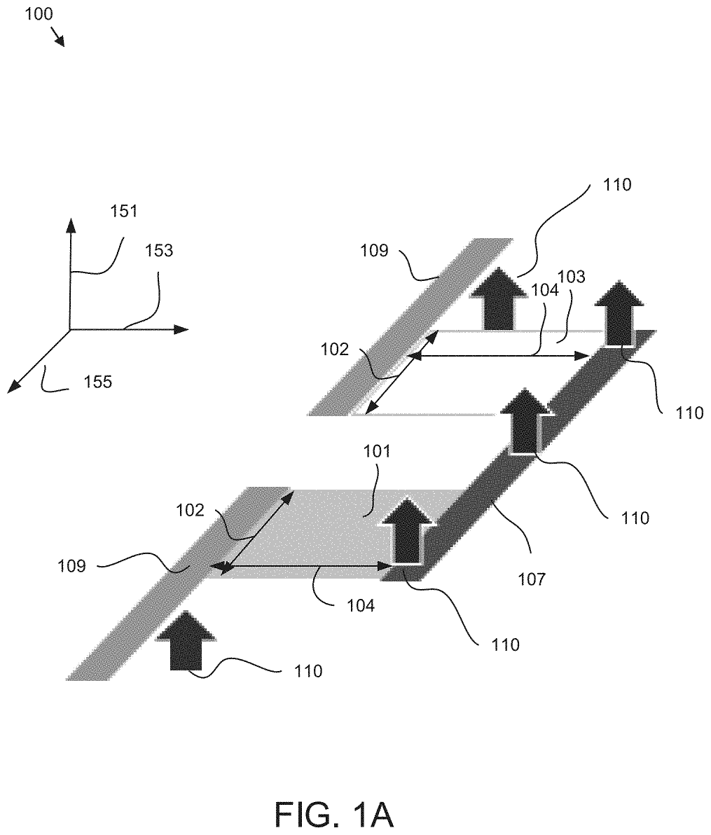

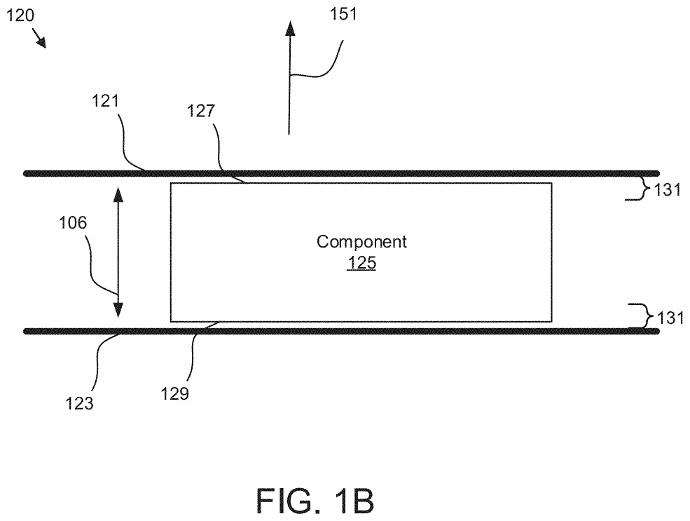

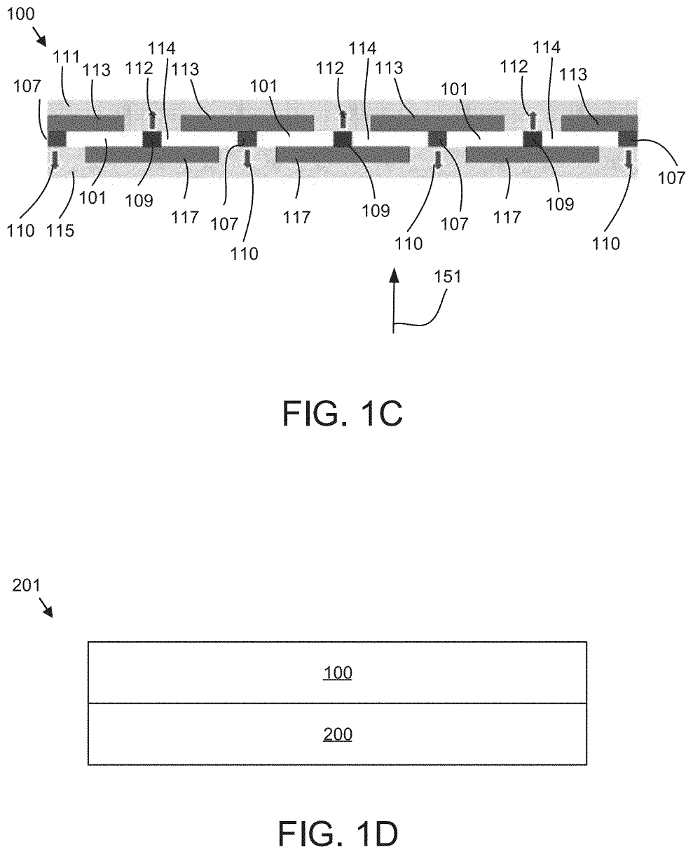

FIG. 1A is a perspective drawing illustrating one embodiment of a thermoelectric device 100. In the depicted embodiment, the thermoelectric device 100 includes a planar p-type semiconductor 101, a planar n-type semiconductor 103, a cold side conductor 107, and a hot side conductor 109. As used herein, the planar p-type semiconductor 101 has a majority of hole charge carriers and the planar n-type semiconductor 103 has a majority of electron charge carriers. In one embodiment, the planar p-type semiconductor 101 and the planar n-type semiconductor 103 are doped.

When a current is applied to the planar p-type semiconductor 101 and the planar n-type semiconductor 103 via the cold side conductor 107 and the hot side conductor 109, the thermoelectric device 100 causes cold 110 to flow, wherein cold is an inverse of heat. Thus, the thermoelectric device 100 may be used to transfer heat. For example, the thermoelectric device 100 may transfer heat from a semiconductor device to cool the semiconductor device.

The planar p-type semiconductor 101 is planar within a first plane that will be described hereafter in FIG. 1B. The planar n-type semiconductor 103 is coplanar with the planar p-type semiconductor 101 within the first plane. The cold side conductor 107 is coplanar with the planar p-type semiconductor 101 and the planar and type semiconductor 103 within the first plane. The cold side conductor 107 connects to the planar p-type semiconductor 101 and to the planar n-type semiconductor 103. The hot side conductor 109 is coplanar with the planar p-type semiconductor 101 and the planar n-type semiconductor 103 within the first plane. The hot side conductor 109 connects to the planar p-type semiconductor 101 and to the planar n-type semiconductor 103.

In the past, thermoelectric devices 100 have been difficult to fabricate, increasing cost. Because the planar p-type semiconductor 101, planar n-type semiconductor 103, cold side conductor 107, and hot side conductor 109 are coplanar within the first plane, fabrication costs are reduced. In addition, the embodiments support the reduction of the thickness of the thermoelectric device 100, improving the efficiency of the thermoelectric device 100.

The thermoelectric device 100 will be described with respect to three axes, a vertical axis 151, a longitudinal axis 153, a latitudinal axis 155. The vertical axis 151 illustrates an up direction from a cold side on the bottom or down to a hot side on the top or up. The planar p-type semiconductor 101 and the planar n-type semiconductor 103 have a length 104 along the longitudinal axis 153 and a width 102 along the latitudinal axis 155.

FIG. 1B is a side view drawing illustrating one embodiment of a first plane 120. As described above, the planar p-type semiconductor 101, planar n-type semiconductor 103, cold side conductor 107, and hot side conductor 109 are coplanar within the first plane 120. A component 125 is shown. The component 125 is selected from the group consisting of the planar p-type semiconductor 101, the planar n-type semiconductor 103, the cold side conductor 107, and the hot side conductor 109. The component 125 is planar and/or coplanar with the first plane 120 in response to the component 125 being between a first plane upper limit 121 and a first plane lower limit 123.

In one embodiment, a top 127 of the component 125 and/or each of the planar p-type semiconductor 101, the planar n-type semiconductor 103, the cold side conductor 107, and the hot side conductor 109 is within a planar limit 131 of the first plane upper limit 121. In addition, a bottom 129 of the component 125 and/or each of the planar p-type semiconductor 101, the planar n-type semiconductor 103, the cold side conductor 107, and the hot side conductor 109 is within the planar limit 131 of the first plane lower limit 123. In a certain embodiment, the component 125 is planar and/or coplanar with the first plane 120 in response to the top 127 being within the planar limit 131 of the first plane upper limit 121 AND the bottom 129 being within the planar limit 131 of the first plan lower limit 123. The planar limit 131 may be in the range of 1 to 100 micrometers.

In one embodiment, the component 125 has a thickness 106 in the vertical axis 151. The ratio of the shortest of the width 102 and the length 104 of the component 125 to the thickness 106 of the component may be in the range of 10-50 to 1. For example, a width 102 of the component 125 may be at least 10 time the thickness 106 of the component 125.

FIG. 1C is a side view drawing illustrating one embodiment of a thermoelectric device 100. The planar p-type semiconductor 101, planar n-type semiconductor 103, cold side conductor 107, and hot side conductor 109 are shown disposed between a cold side substrate 115 on the bottom and a hot side substrate 111 on the top. As shown, the hot side substrate 111 may be in thermal contact with the hot side conductor 109. The cold side substrate 115 may be in thermal contact with the cold side conductor 107.

However, a cold side thermal insulator 117 may insulate the hot side conductor 107 from the cold side substrate 115. In addition, a hot side thermal insulator 113 may insulate the cold side conductor 107 from the hot side substrate 111.

The cold side conductor 107 draws heat 112 from the cold side substrate 115 and the hot side substrate 111 directs the heat 112 to the hot side substrate 111 in response to an electric current applied between the cold side conductor 107 and the hot side conductor 109.

FIG. 1D is a side view drawing illustrating one embodiment of a cooling system 201. In the depicted embodiment, the thermoelectric device 100 is disposed in physical contact with a heat source 200. The thermoelectric device 100 may cool the heat source 200. The heat source 200 may be a semiconductor device.

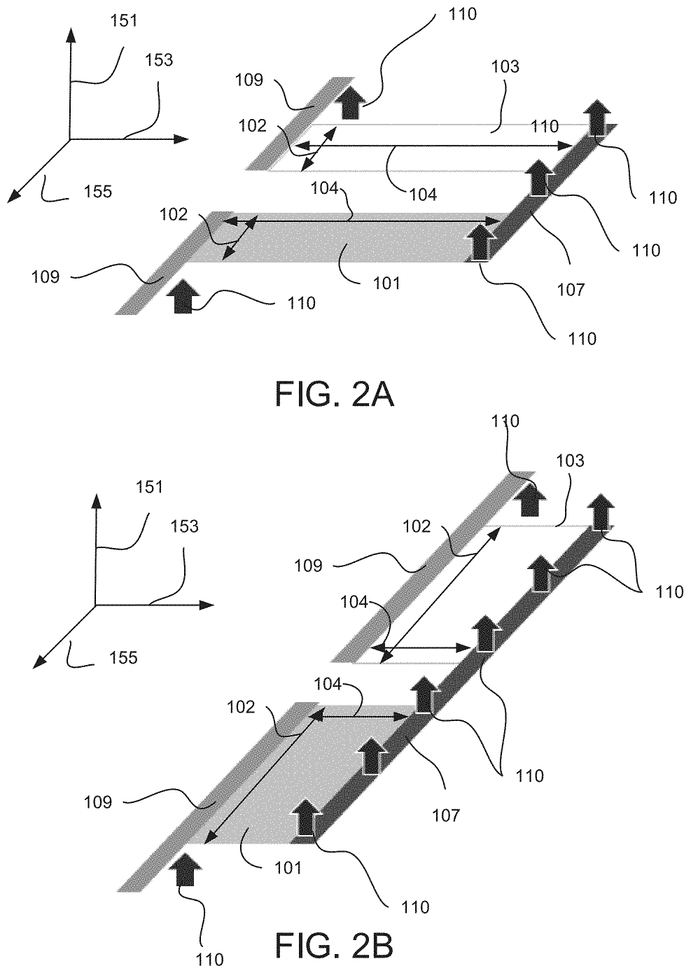

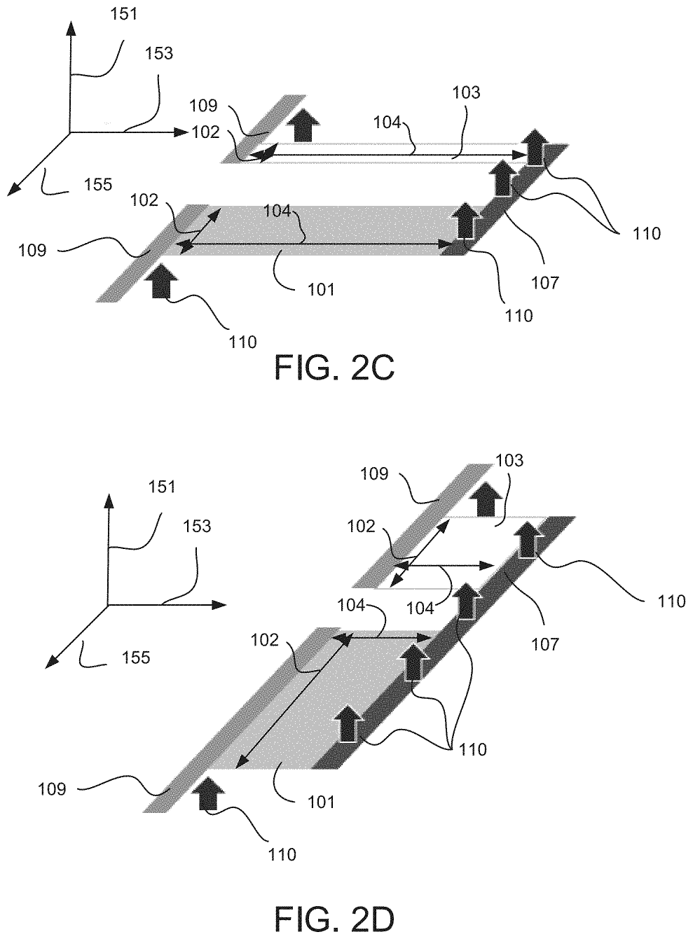

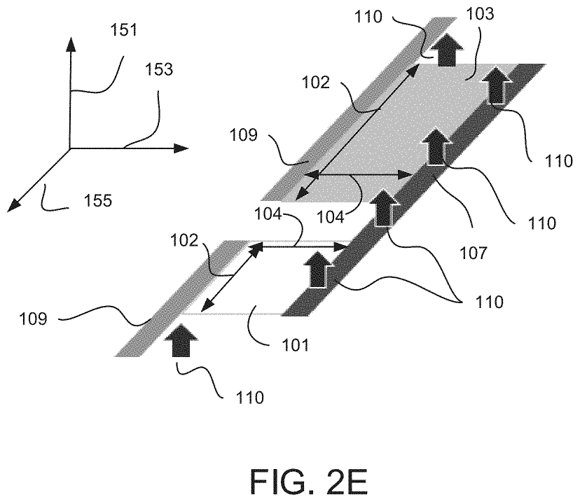

FIG. 2A is a perspective drawing illustrating one alternate embodiment of the thermoelectric device 100. In the depicted embodiment, the planar p-type semiconductor 101, the planar n-type semiconductor 103, the cold side conductor 107, and the hot side conductor 109 are shown. In addition, the planar p-type semiconductor 101 and the planar n-type semiconductor 103 are longer in length 104 along the longitudinal axis 153 than in width 102 along the latitudinal axis 155. In one embodiment, the ratio of longitudinal axis length 104 to latitudinal axis width 102 is in the range of 1.5-6 to 1.

FIG. 2B is a perspective drawing illustrating one alternate embodiment of the thermoelectric device 100. In the depicted embodiment, the planar p-type semiconductor 101, the planar n-type semiconductor 103, the cold side conductor 107, and the hot side conductor 109 are shown. In addition, the planar p-type semiconductor 101 and the planar n-type semiconductor 103 are wider in width 102 along the latitudinal axis 155 than in length 104 along the longitudinal axis 153. In one embodiment, the ratio of latitudinal axis width 102 to longitudinal axis length 104 is in the range of 1.5-6 to 1.

FIG. 2C is a perspective drawing illustrating one alternate embodiment of the thermoelectric device 100. In the depicted embodiment, the planar p-type semiconductor 101, the planar n-type semiconductor 103, the cold side conductor 107, and the hot side conductor 109 are shown. The planar p-type semiconductor 101 and the planar n-type semiconductor 103 are longer in length 104 along the longitudinal axis 153 than in width 102 along the latitudinal axis 155. In addition, the planar p-type semiconductor 101 is wider in width 102 along the latitudinal axis 155 than the planar n-type semiconductor 103. In one embodiment, the ratio of the latitudinal axis width 102 for the p-type semiconductor 101 to the latitudinal axis width 102 for the n-type semiconductor 103 is in the range of 1.25-4 to 1.

FIG. 2D is a perspective drawing illustrating one alternate embodiment of the thermoelectric device 100. In the depicted embodiment, the planar p-type semiconductor 101, the planar n-type semiconductor 103, the cold side conductor 107, and the hot side conductor 109 are shown. The planar p-type semiconductor 101 and the planar n-type semiconductor 103 are wider in width 102 in the latitudinal axis 155 than in length 104 along the longitudinal axis 153. In one embodiment, the ratio of latitudinal axis width 102 to longitudinal axis length 104 is in the range of 1.5-6 to 1.

In the depicted embodiment, the width 102 of the p-type semiconductor 101 is greater than the width 102 of the n-type semiconductor 103. The ratio of the width 102 of the p-type semiconductor 101 to the width 102 of the n-type semiconductor 103 may be in the range of 1.25-4 to 1.

FIG. 2E is a perspective drawing illustrating one alternate embodiment of the thermoelectric device 100. In the depicted embodiment, the planar p-type semiconductor 101, the planar n-type semiconductor 103, the cold side conductor 107, and the hot side conductor 109 are shown. In addition, the planar p-type semiconductor 101 and the planar n-type semiconductor 103 are wider in width 102 in the latitudinal axis 155 than in length 104 along the longitudinal axis 153. In one embodiment, the ratio of latitudinal axis width 102 to longitudinal axis length 104 is in the range of 1.5-6 to 1.

In the depicted embodiment, the width 102 of the p-type semiconductor 101 is greater than the width 102 of the n-type semiconductor 103. The ratio of the width 102 of the p-type semiconductor 101 to the width 102 of the n-type semiconductor 103 may be in the range of 1.25-4 to 1.

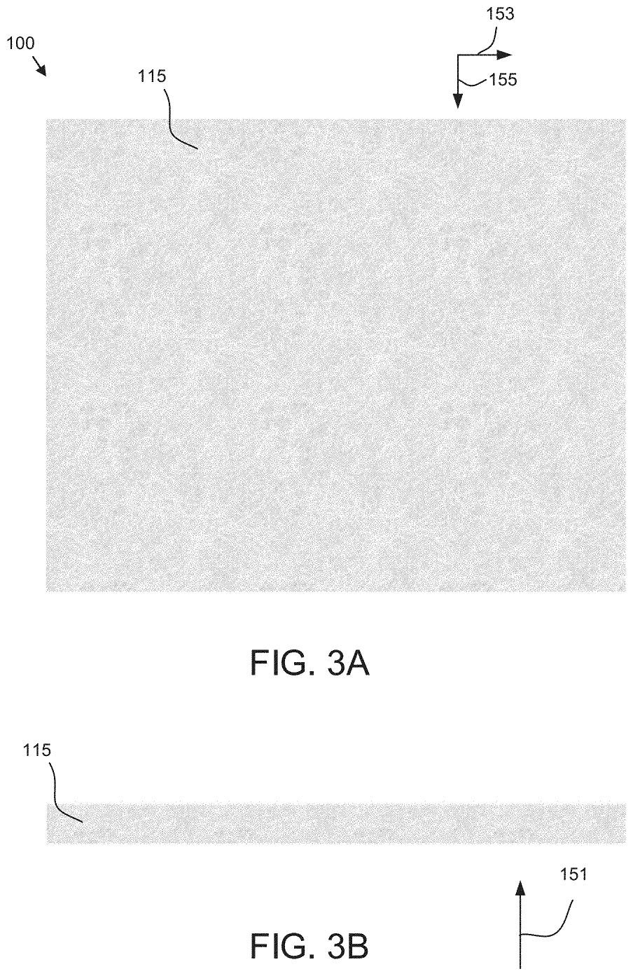

FIG. 3A is a top view drawing illustrating one embodiment of cold side substrate 115 in a fabrication process. The cold side substrate 115 and the hot side substrate 111 may be ceramic, metal, or combinations thereof. In one embodiment, at least one of the hot side substrate 111 and the cold site substrate 115 are ceramic. Metal may be used to reduce the thickness along the vertical axis 151 of the cold side substrate 115 and/or hot side substrate 111. In addition, metal may be used to increase the flexibility of the thermoelectric device 100. The cold side substrate 115 and the hot side substrate 111 may be selected using Table 1.

TABLE 1

| cold side | hot side |
|---|---|
| substrate 115 | substrate 111 |
| Ceramic | Ceramic |
| Ceramic | Metal |
| Metal | Ceramic |
| Metal | Metal |

In one embodiment, metal is used to contour the thermoelectric device 100 to a target device. For example, metal may be used in the cold side substrate 115 and the hot side substrate 111 to contour the thermoelectric device 100 to a cylindrical system. The use of metal in the cold side substrate 115 and the hot side substrate 111 may increase contact between the thermoelectric device 100 and the target device.

FIG. 3B is a side view drawing illustrating one embodiment of cold side substrate 115 in a fabrication process.

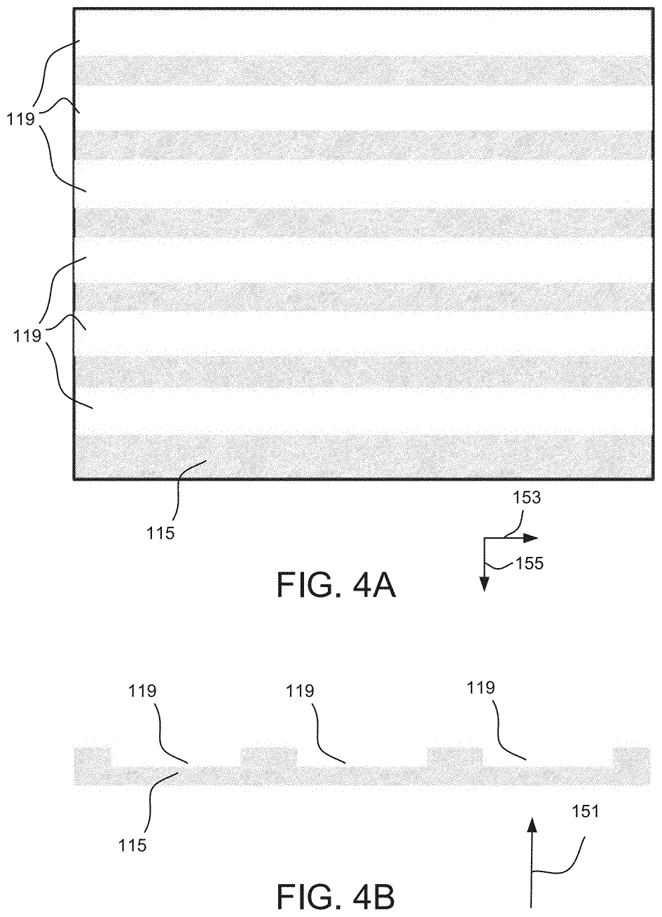

FIG. 4A is a top view drawing illustrating one embodiment of grooving in a fabrication process. In the depicted embodiment, grooves 119 are cut in the cold side substrate 115. The grooves 119 may be milled, ion milled, etched, and the like. A similar process may form grooves 119 in the hot side substrate 111. In one embodiment, at least one of the hot side thermal insulator 113 and the cold side thermal insulator 117 are disposed in a groove 119.

FIG. 4B is a side view drawing illustrating one embodiment of grooving in a fabrication process. The grooves 119 are shown in the cold side substrate 115.

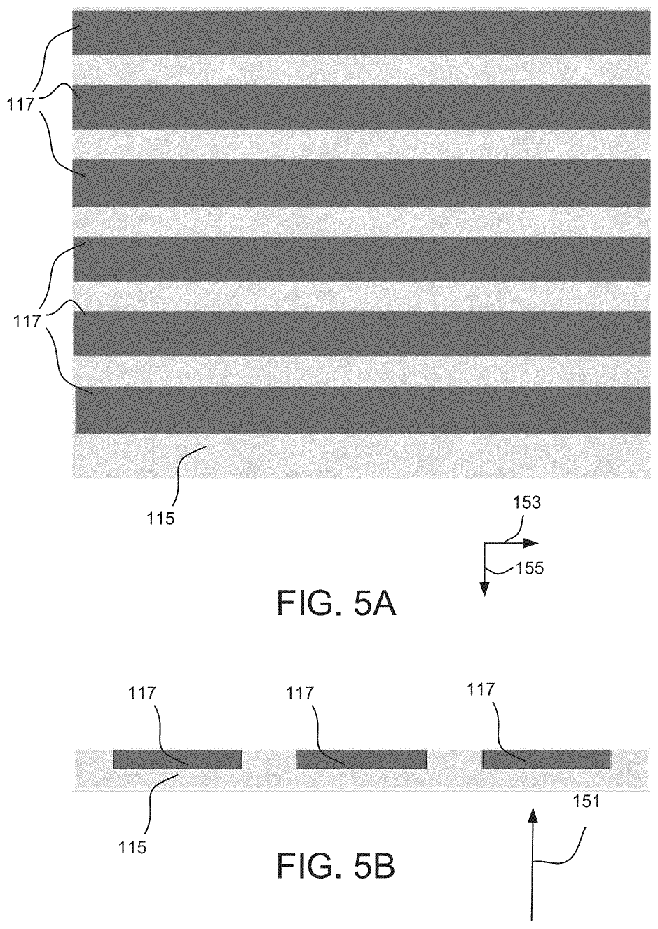

FIG. 5A is a top view drawing illustrating one embodiment of thermal insulator deposition in a fabrication process. In the depicted embodiment, the cold side thermal insulator 117 is deposited in the grooves 119. The cold side thermal insulator 117 may be deposited using a deposition oven and/or sputter. A similar process may deposit the hot side thermal insulator 113 in grooves 119 of the hot side substrate 111.

In one embodiment, at least one of the hot side thermal insulator 113 and the cold side thermal insulator 117 are aero gels. In a certain embodiment, the hot side thermal insulator 113 and/or the cold side thermal insulator 117 is at least 99.8 percent air.

FIG. 5B is a side view drawing illustrating one embodiment of thermal insulator deposition in a fabrication process for the cold side substrate 115. In the depicted embodiment, the cold side thermal insulator 117 is deposited in the grooves 119. The hot side thermal insulator 113 may be similarly deposited in grooves 119 of the hot side substrate 111.

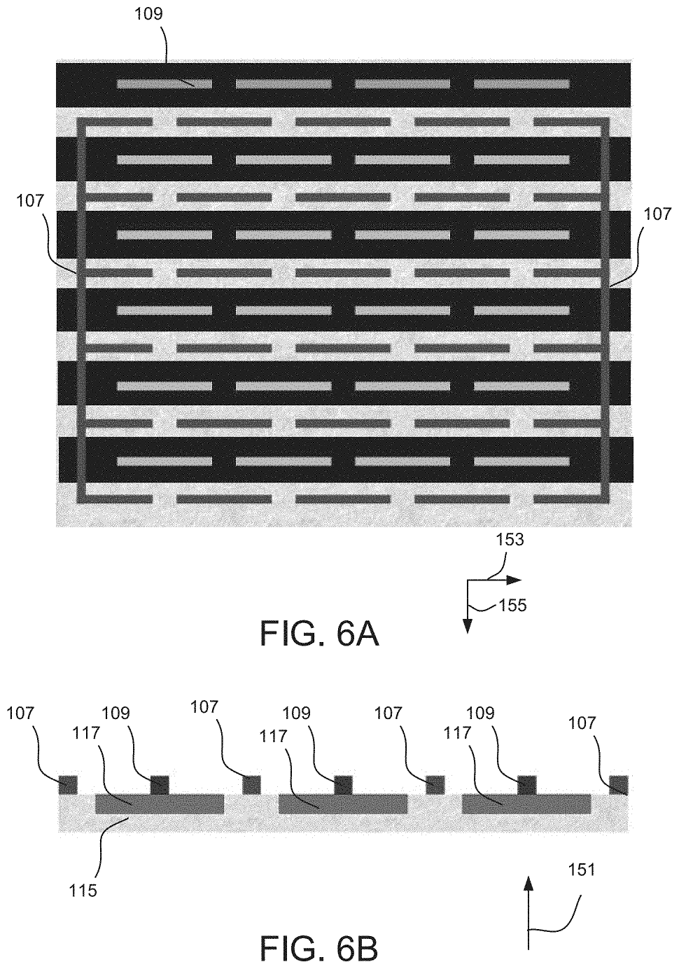

FIG. 6A is a top view drawing illustrating one embodiment of conductor deposition in a fabrication process. In the depicted embodiment, the cold side conductor 107 and the hot side conductor 109 are deposited on the cold side substrate 115 and cold side thermal insulator 117 for the thermoelectric device 100. The cold side conductor 107 and the hot side conductor 109 may also be deposited on the hot side substrate 111 and the hot side thermal insulator 113. The cold side conductor 107 and/or the hot side conductor 109 may be deposited using a deposition oven and/or sputterer.

FIG. 6B is a side view drawing illustrating one embodiment of conductor deposition in a fabrication process. The cold side conductor 107 and the hot side conductor 109 are shown deposited on the cold side substrate 115 and the cold side thermal insulator 117. Alternatively, the cold side conductor 107 and the hot side conductor 109 may be deposited on the hot side substrate 111 and the hot side thermal insulator 113.

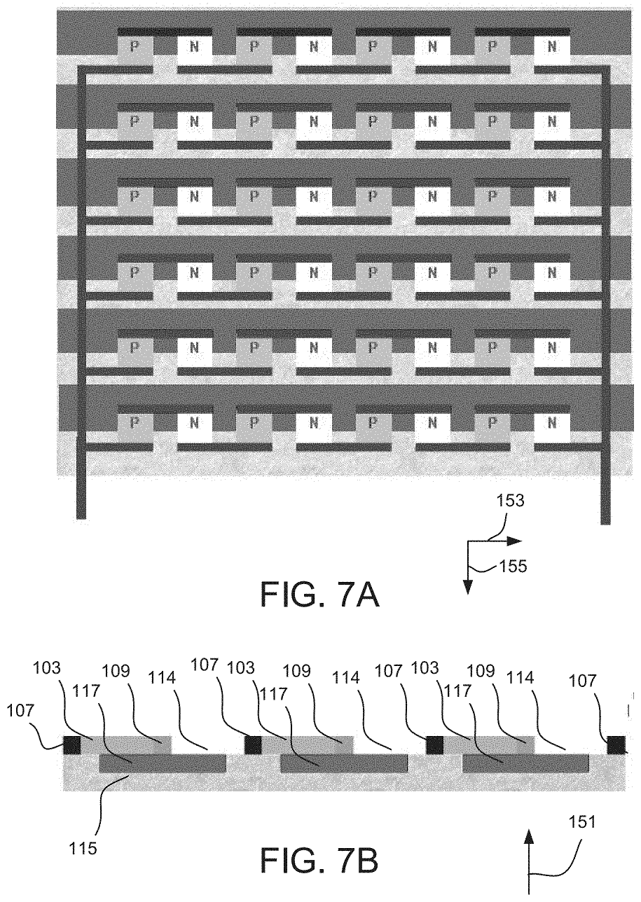

FIG. 7A is a top view drawing illustrating one embodiment of p-type semiconductor and n-type semiconductor deposition in a fabrication process. In the depicted embodiment, the planar p-type semiconductor 101, labeled ‘P’ for clarity, and the planar n-type semiconductor 103, labeled ‘N’ for clarity are deposited on the cold side substrate 115 and the cold side thermal insulator 117. Alternatively, the planar p-type semiconductor 101 and the planar n-type semiconductor 103 may be deposited on the hot side substrate 111 and the hot side thermal insulator 113.

FIG. 7B is a side view drawing illustrating one embodiment of p-type semiconductor and n-type semiconductor deposition in a fabrication process. In the depicted embodiment, the planar p-type semiconductor 101 and the planar n-type semiconductor 103 are deposited on the cold side substrate 115 and the cold side thermal insulator 117. Alternatively, the planar p-type semiconductor 101 and the planar n-type semiconductor 103 may be deposited on the hot side substrate 111 and the hot side thermal insulator 113.

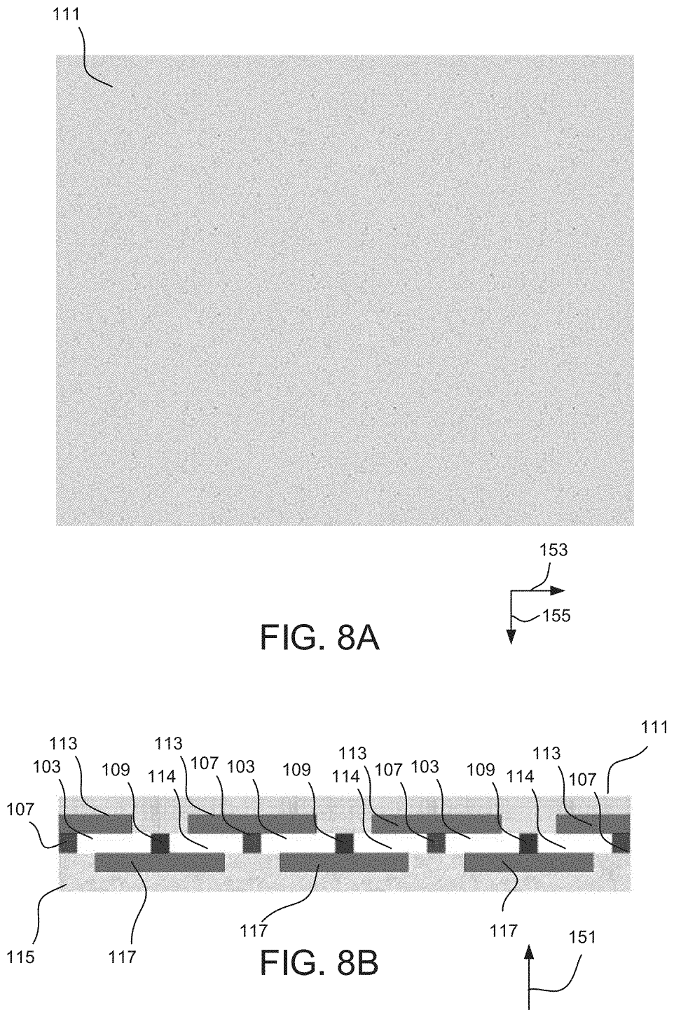

FIG. 8A is a top view drawing illustrating one embodiment of hot side substrate deposition in a fabrication process. In the depicted embodiment, the hot side substrate 111 is added to the thermoelectric device 100. In one embodiment, a hot side substrate 111 is grooved as shown in FIGS. 4A-B. In addition, the hot side thermal insulator 113 may be deposited in the grooves 119 of the hot side substrate 111 as shown in FIGS. 5A-B. The ceramic hot side substrate 111 may then be added to the thermoelectric device 100.

FIG. 8B is a side view drawing illustrating one embodiment of hot side thermal insulator deposition in a fabrication process. In one embodiment, the grooved hot side substrate 111 with hot side thermal insulator 113 is added to the thermoelectric device 100. In an alternative embodiment, the hot side thermal insulator 113 is deposited on the thermoelectric device 100. The hot side substrate 111 may be subsequently deposited on the thermoelectric device 100.

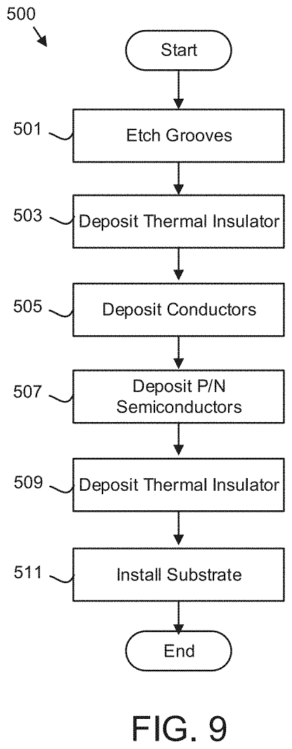

FIG. 9 is a schematic flow chart diagram illustrating one embodiment of a thermoelectric device fabrication method 500. The method 500 may fabricate the thermoelectric device 100. In the depicted embodiment, the method 500 begins with the cold side substrate 115. However, the method 500 may be reversed and begin with the hot side substrate 111.

The method 500 starts and etches 501 grooves 119 in the cold side substrate 115 and the hot side substrate 111. The method 500 may etch 501 grooves 119 as shown in FIGS. 4A-B.

The method 500 deposits 503 the cold side thermal insulator 117. The method 500 may deposit 503 the cold side thermal insulator 117 on the cold side substrate 115. The cold side thermal insulator 117 may be deposited 503 as shown in FIGS. 5A-B.

The method 500 may deposit 505 the cold side conductor 107 and the hot side conductor 109. The cold side conductor 107 and the hot side conductor 109 may be deposited 505 on the cold side substrate 115 and the cold side insulator 117. Alternatively, the cold side conductor 107 and the hot side conductor 109 may be deposited 505 on the hot side substrate 111 and the hot side thermal insulator 113. The cold side conductor 107 and the hot side conductor 109 may be deposited 505 as shown in FIG. 6A-B.

The method 500 may deposit 507 the planar p-type semiconductor 101 and the planar n-type semiconductor 103. The planar p-type semiconductor 101 and the planar n-type semiconductor 103 may be deposited 507 on the cold side substrate 115 and the cold side insulator 117. Alternatively, planar p-type semiconductor 101 and the planar n-type semiconductor 103 may be deposited 507 on the hot side substrate 111 and the hot side thermal insulator 113. The planar p-type semiconductor 101 and the planar n-type semiconductor 103 may be deposited 507 as shown in FIGS. 7A-B.

The method 500 may deposit 509 the hot side thermal insulator 113 in the hot side substrate 111. The hot side thermal insulator 113 may be deposited 503 as shown in FIGS. 5A-B. Alternatively, the method 500 may deposits 509 the cold side thermal insulator 117.

The method 500 may install 511 the hot side substrate 111 and the method ends. The hot side substrate 111 may be installed 511 as described in FIGS. 8A-B. Alternatively, the cold side substrate 115 may be installed 511.

In the past, thermoelectric devices 100 have been thick with high costs and low efficiency. The embodiments provide a thermoelectric device 100 with increased efficiency. In addition, the embodiments provide the thermoelectric device 100 with a more cost-effective fabrication process. The embodiments may also provide the thermoelectric device 100 with reduced thickness and reduced material consumption.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A thermoelectric device comprising:
a planar p-type semiconductor that is planar within a first plane;
a planar n-type semiconductor that is coplanar with the planar p-type semiconductor within the first plane;
a cold side conductor that is coplanar with the planar p-type semiconductor and the planar n-type semiconductor within the first plane and that connects to the planar p-type semiconductor and to the planar n-type semiconductor;
a hot side conductor that is coplanar with the planar p-type semiconductor and the planar n-type semiconductor within the first plane and that connects to the planar p-type semiconductor and to the planar n-type semiconductor;
a hot side substrate in thermal contact with the hot side conductor;
a hot side thermal insulator that insulates the cold side conductor from the host side substrate;
a cold side substrate in thermal contact with the cold side conductor;
a cold side thermal insulator that insulates the hot side conductor from the cold side substrate; and
wherein the cold side conductor draws heat from the cold side substrate and the hot side conductor directs the heat to the hot side substrate in response to an electric current applied between the cold side conductor and the hot side conductor.

2. The thermoelectric device of claim 1, wherein at least one of the hot side thermal insulator and the cold side thermal insulator is an aero gel.

3. The thermoelectric device of claim 1, wherein at least one of the hot side thermal insulator and the cold side thermal insulator is disposed in a groove.

4. The thermoelectric device of claim 1, wherein at least one of the hot side substrate and the cold side substrate is ceramic.

5. The thermoelectric device of claim 1, wherein at least one of the hot side substrate and the cold side substrate is metal.

6. The thermoelectric device of claim 1, wherein a component selected from the group consisting of the planar p-type semiconductor, the planar n-type semiconductor, the cold side conductor, and the hot side conductor is planar within the first plane in response to the component being between a first plane upper limit and a first plane lower limit.

7. The thermoelectric device of claim 1, wherein a top of each of the planar p-type semiconductor, the planar n-type semiconductor, the cold side conductor, and the hot side conductor is within a planar limit of a first plane upper limit and a bottom of each of the planar p-type semiconductor, the planar n-type semiconductor, the cold side conductor, and the hot side conductor is within the planar limit of a first plane lower limit.

8. A system comprising:
a heat source;
a thermoelectric device comprising:
a planar p-type semiconductor that is planar within a first plane;
a planar n-type semiconductor that is coplanar with the planar p-type semiconductor within the first plane;
a cold side conductor that is coplanar with the planar p-type semiconductor and the planar n-type semiconductor within the first plane and that connects to the planar p-type semiconductor and to the planar n-type semiconductor;
a hot side conductor that is coplanar with the planar p-type semiconductor and the planar n-type semiconductor within the first plane and that connects to the planar p-type semiconductor and to the planar n-type semiconductor;
a hot side substrate in thermal contact with the hot side conductor;
a hot side thermal insulator that insulates the cold side conductor from the host side substrate;
a cold side substrate in thermal contact with the cold side conductor and the heat source;
a cold side thermal insulator that insulates the hot side conductor from the cold side substrate; and
wherein the cold side conductor draws heat from the cold side substrate and the hot side conductor directs the heat to the hot side substrate in response to an electric current applied between the cold side conductor and the hot side conductor.

9. The system of claim 8, wherein at least one of the hot side thermal insulator and the cold side thermal insulator is an aero gel.

10. The system of claim 8, wherein at least one of the hot side thermal insulator and the cold side thermal insulator is disposed in a groove.

11. The system of claim 8, wherein at least one of the hot side substrate and the cold side substrate is ceramic.

12. The system of claim 8, wherein at least one of the hot side substrate and the cold side substrate is metal.

13. The system of claim 8, wherein a component selected from the group consisting of the planar p-type semiconductor, the planar n-type semiconductor, the cold side conductor, and the hot side conductor is planar within the first plane in response to the component being between a first plane upper limit and a first plane lower limit.

14. The system of claim 8, wherein a top of each of the planar p-type semiconductor, the planar n-type semiconductor, the cold side conductor, and the hot side conductor is within a planar limit of a first plane upper limit and a bottom of each of the planar p-type semiconductor, the planar n-type semiconductor, the cold side conductor, and the hot side conductor is within the planar limit of a first plane lower limit.

15. A method comprising:
etching grooves in a cold side substrate and/or a hot side substrate;
depositing a cold side thermal insulator in the cold side substrate;
depositing a cold side conductor and a hot side conductor;
depositing a p-type semiconductor and a planar n-type semiconductor;
depositing a hot side thermal insulator in the hot side substrate;
installing a hot side substrate, wherein:
the planar p-type semiconductor is planar within a first plane;
the planar n-type semiconductor is coplanar with the planar p-type semiconductor within the first plane;
the cold side conductor is coplanar with the planar p-type semiconductor and the planar n-type semiconductor within the first plane and connects to the planar p-type semiconductor and to the planar n-type semiconductor;
the hot side conductor is coplanar with the planar p-type semiconductor and the planar n-type semiconductor within the first plane and connects to the planar p-type semiconductor and to the planar n-type semiconductor;
the hot side substrate is in thermal contact with the hot side conductor;
the hot side thermal insulator insulates the cold side conductor from the host side substrate;
the cold side substrate is in thermal contact with the cold side conductor;
the cold side thermal insulator insulates the hot side conductor from the cold side substrate; and
the cold side conductor draws heat from the cold side substrate and the hot side conductor directs the heat to the hot side substrate in response to an electric current applied between the cold side conductor and the hot side conductor.

16. The system of claim 15, wherein at least one of the hot side thermal insulator and the cold side thermal insulator is an aero gel.

17. The system of claim 15, wherein at least one of the hot side thermal insulator and the cold side thermal insulator is disposed in a groove.

18. The system of claim 15, wherein at least one of the hot side substrate and the cold side substrate is ceramic.

19. The system of claim 15, wherein a component selected from the group consisting of the planar p-type semiconductor, the planar n-type semiconductor, the cold side conductor, and the hot side conductor is planar within the first plane in response to the component being between a first plane upper limit and a first plane lower limit.

20. The system of claim 15, wherein a top of each of the planar p-type semiconductor, the planar n-type semiconductor, the cold side conductor, and the hot side conductor is within a planar limit of a first plane upper limit and a bottom of each of the planar p-type semiconductor, the planar n-type semiconductor, the cold side conductor, and the hot side conductor is within the planar limit of a first plane lower limit.
